(19) United States
(12) Patent Application Publication
(10) Pub. No.: US 2017/0186932 A1
(43) Pub. Date: Jun. 29, 2017

(54) SPIN THERMOELECTRIC DEVICE

(71) Applicant: UNIST (ULSAN NATIONAL INSTITUTE OF SCIENCE AND TECHNOLOGY), Ulsan (KR)

(72) Inventors: Ki-Suk LEE, Ulsan (KR); Min-Sun JANG, Ulsan (KR)

(73) Assignee: UNIST (ULSAN NATIONAL INSTITUTE OF SCIENCE AND TECHNOLOGY), Ulsan (KR)

(21) Appl. No.: 15/383,482

(22) Filed: Dec. 19, 2016

(30) Foreign Application Priority Data
Dec. 23, 2015 (KR) 10-2015-0185266

(51) Int. Cl. H01L 35/32; H02S 10/30; H01L 35/20

(52) U.S. Cl. CPC H01L 35/32; H01L 35/20; H02S 10/30

(57) ABSTRACT

Disclosed is a spin thermoelectric device comprising: a transparent base material; and a plurality of spin thermoelectric elements and a plurality of electrode pads which are provided on the base material, wherein the spin thermoelectric element comprises a thermoelectric layer formed by a sol-gel method and made of a material that shows a spin Seebeck effect caused by a temperature gradient based on a heat source, and an electrode layer formed on the thermoelectric layer. The spin thermoelectric device is applicable to cladding of building, a greenhouse, etc. and used as a light source for lighting and a heat source for cooling/heating in such a manner that it transmits light and is charged with electricity when there is sunlight or there is difference in temperature between the inside of the building and the outside and it discharges electricity when there is no sunlight or there are no differences in temperature between the inside of the building and the outside.

### CROSS-REFERENCE TO RELATED APPLICATION

This application claims priority to and the benefit of Korean Patent Application No. 10-2015-0185266 filed in the Korean Intellectual Property Office on Dec. 23, 2015, the entire contents of which are incorporated herein by reference.

### BACKGROUND OF THE INVENTION

(a) Field of the Invention

The present invention relates to a spin thermoelectric device, and more particularly to a spin thermoelectric device in which a spin thermoelectric element manufactured by a sol-gel method is applied to a transparent base material.

(b) Description of the Related Art

As dealing with environment and energy problems has recently become important for a sustainable society, expectations of a thermoelectric conversion element are growing. The reason is because heat is the most general energy source that can be obtained from various media such as body heat, sunlight, an engine, an industrial heat, etc.

Therefore, it is expected that the thermoelectric element becomes more and more important in future in order to increase efficiency in using energy under a low-carbon society, feed power to a ubiquitous terminal/sensor, and so on.

As a conventional structure of the thermoelectric element, a bulk type thermoelectric conversion element, in which a sintered body of a thermoelectric semiconductor such as Bi₂Te₃ is treated/bonded to assemble a thermocouple module, is general. However, a thin-film type thermoelectric element, in which a thin film of a thermoelectric semiconductor is grown on a substrate by sputtering or the like method to make a module, has recently been developed and attracted attention.

Advantageously, such a thin-film type thermoelectric element is small and lightweight, makes it possible to form a film on a large area in a lump by sputtering, applying/printing or the like method and thus increase productivity, and reduces costs since an inexpensive substrate is applicable.

Hitherto, the thin-film type thermoelectric element has been manufactured by an applying or printing method. For example, a paste made by mixing Bi₂Te₃ powder with a binder is applied on to a substrate by a screen printing or the like method to form a thermoelectric element pattern. Further, ink that includes a thermoelectric semiconductor material and an electrode material is patterned and printed by an ink-jet method, thereby forming the thermoelectric element. In addition, an organic semiconductor is used as the thermoelectric material to thereby form the thermoelectric element by a printing process.

However, there was a problem that it is difficult to create/keep difference in temperature between a thin film surface and its rear surface since the thin-film type thermoelectric element is given as a thin film. That is, for many purposes of power generation, thermoelectric conversion is carried out by applying a temperature difference (i.e. a temperature gradient) in a direction perpendicular to the thin film surface including the thermoelectric material. By the way, thermal insulation (i.e. thermal resistance) becomes insufficient as the thin film of the thermoelectric semiconductor gets thinner. Therefore, it becomes difficult to keep the difference in temperature between the thin film surface and the rear surface of the thermoelectric semiconductor. Further, the difference in temperature is mostly caused in not between the thin film surface and the rear surface of thermoelectric semiconductor but between the surface of the substrate and the rear surface, and thus power is not efficiently generated.

The thermal insulation may be improved by either increasing the thickness of the thermoelectric semiconductor film (for example, to be thicker than several tens of μm) or decreasing the thermal conductivity of the thermoelectric semiconductor. In the case of increasing the thickness of the film, it is difficult to pattern/manufacture a thermocouple structure by the applying/printing process or the like, thereby lowering the productivity. Thus, there is a trade-off between efficiency of high-conversion and productivity of low costs.

The lower the thermal conductivity, the lower the electric conductivity. Therefore, a conventional thermoelectric power-generation employs a thermoelectric material having a high electric conductivity. Since there is a trade-off between the electric conductivity and the thermal conductivity, there is a limit to decreasing the thermal conductivity.

By the way, a flow of electron spin is observed when a temperature gradient is applied to a magnetic material, which is called the spin Seebeck effect.

The thermoelectric element has a structure including a ferromagnetic metal film and a metal electrode which are grown by the sputtering method. With this structure, if the temperature gradient is applied in directions parallel with and perpendicular to the surface of the ferromagnetic metal film, a spin flow is induced in the direction of the temperature gradient by the spin Seebeck effect. The induced spin flow is turned into an electric current by the inverse spin hall effect in the metal electrode being in contact with the ferromagnetic metal. Thus, it is possible to turn heat into power based on the temperature difference.

FIG. 11 shows a cross-section of a spin thermoelectric element that includes a thermoelectric layer made of Y₃Fe₅O₁₂ (Yttrium Iron Garnet, YIG) and an electrode layer made of platinum (Pt).

If the temperature gradient is applied to the thermoelectric layer, spin-up electrons are densely accumulated in a section having a relatively low temperature and spin-down electrons are densely accumulated in a section having a relatively high temperature.

Difference in such a spin density causes difference in chemical potential, and thus electricity is produced using the chemical potential difference.

On the contrary to the conventional thermoelectric conversion element using the structure of the thermocouple module, the spin Seebeck effect does not need such a complicated thermocouple structure and thus solves a problem of patterning the foregoing structure, thereby achieving a thin film thermoelectric element that can be made to have a large area with low costs.

Further, the thermoelectric conversion element based on the spin Seebeck effect can have a structure with high electric conductivity (of decreasing ohmic loss) and low thermal conductivity (of keeping difference in temperature between the surface and the rear surface) since an electrically conductive part (i.e. an electrode) and a thermally conductive part (i.e. a magnetic body) are independently designed.

Accordingly, there is a need of developing a device having an optimized structure applicable to various applications using the thermoelectric element.

### RELATED REFERENCE

### Patent Document

(Patent document 1) Korean Patent No. 0904666

### SUMMARY OF THE INVENTION

Accordingly, the present invention is conceived to solve the forgoing shortcomings and problems of the conventional spin thermoelectric device, and an aspect of the present invention is to provide a spin thermoelectric device in which a spin thermoelectric element having a thermoelectric layer manufactured by a sol-gel method is applied to a transparent base material.

In accordance with an aspect of the present invention, there is provided a spin thermoelectric device comprising: a transparent base material; and a plurality of spin thermoelectric elements and a plurality of electrode pads which are provided on the base material, wherein the spin thermoelectric element comprises a thermoelectric layer formed by a sol-gel method and made of a material that shows a spin Seebeck effect caused by a temperature gradient based on a heat source, and an electrode layer formed on the thermoelectric layer.

Here, the spin thermoelectric element may further comprise a concentrator photovoltaics (CPV) formed on the electrode layer. The electrode pad is used in outputting electricity generated in the spin thermoelectric element to an outside. The transparent base material may comprise a polyester (PET) film or a polydimethylsiloxane (PDMS) film, and may be flexible. The thermoelectric layer comprises yttrium iron garnet (YIG, Y₃Fe₅O₁₂).

In accordance with another aspect of the present invention, there is provided a spin thermoelectric device comprising: a transparent base material; a groove formed on the base material; an electrode pad filled in the groove; and a plurality of spin thermoelectric elements provided on the base material and the groove, wherein the spin thermoelectric element comprises a thermoelectric layer formed by a sol-gel method and made of a material that shows a spin Seebeck effect caused by a temperature gradient based on a heat source.

Here, the spin thermoelectric element may further comprise a concentrator photovoltaics (CPV) formed on the electrode layer. The electrode pad is used in outputting electricity generated in the spin thermoelectric element to an outside. The transparent base material may comprise a polyester (PET) film or a polydimethylsiloxane (PDMS) film, and may be flexible. The thermoelectric layer comprises yttrium iron garnet (YIG, Y₃Fe₅O₁₂).

In accordance with still another aspect of the present invention, there is provided a greenhouse comprising the foregoing spin thermoelectric device, a rechargeable battery to be charged with electricity generated in the spin thermoelectric device, and a light emitting diode (LED) or a light bulb is provided on a side opposite to the side where the spin thermoelectric element of the spin thermoelectric device is formed, so that electricity can be charged when there is sunlight or a heat source, but the electricity can be discharged to emit light when there are no heat sources.

### BRIEF DESCRIPTION OF THE DRAWINGS

The above and/or other aspects of the present invention will become apparent and more readily appreciated from the following description of the exemplary embodiments, taken in conjunction with the accompanying drawings, in which:

FIG. 1 is a perspective view of a spin thermoelectric element in a spin thermoelectric device according to an embodiment of the present invention;

FIG. 2 is a perspective view of a hybrid spin thermoelectric element in a spin thermoelectric device according to an embodiment of the present invention;

FIG. 3 is a cross-section view of a spin thermoelectric element in a spin thermoelectric device according to an embodiment of the present invention;

FIG. 4 is a cross-section view of a hybrid spin thermoelectric element in a spin thermoelectric device according to an embodiment of the present invention;

FIG. 5 is a perspective view of a spin thermoelectric device according to an embodiment of the present invention;

FIG. 6 is a perspective view of a spin thermoelectric device according to an embodiment of the present invention;

FIG. 7 is a perspective view of a spin thermoelectric device according to another embodiment of the present invention;

FIG. 8 is a perspective view of a spin thermoelectric device according to another embodiment of the present invention;

FIG. 9 is a cross-section view of a spin thermoelectric device according to another embodiment of the present invention;

FIG. 10 is a cross-section view of a spin thermoelectric device according to another embodiment of the present invention;

FIG. 11 is a schematic view for explaining a mechanism of spin Seebeck effect; and

FIG. 12 illustrates one of the application fields of the spin thermoelectric device per the present invention.

### DETAILED DESCRIPTION OF THE EMBODIMENTS

The merits and features of the present invention and techniques for achieving the same will become clear by embodiments described in detail with reference to accompanying drawings. However, the present invention is not limited to the embodiments set forth herein, but may be embodied in various forms. The following embodiments are provided to complete the disclosure of the invention and shown the scope of the invention to a person having an ordinary skill in the art.

Terms used in this specification are given just for describing the embodiments and not construed to limit the scope of the present invention. In this specification, a singular form of an element involves a plurality of elements unless otherwise specified. Further, ‘comprise/include/have’ and/or ‘comprising/including/having’ used for an element, a step, an operation and/or a device does not exclude one or more additional elements, steps, operations and/or devices.

The technical features and effects of the spin thermoelectric device according to the aspects of the present invention will be clearly understood from the following description of the exemplary embodiments with reference to the accompanying drawings.

Below, the present invention will be described in detail with reference to the accompanying drawings.

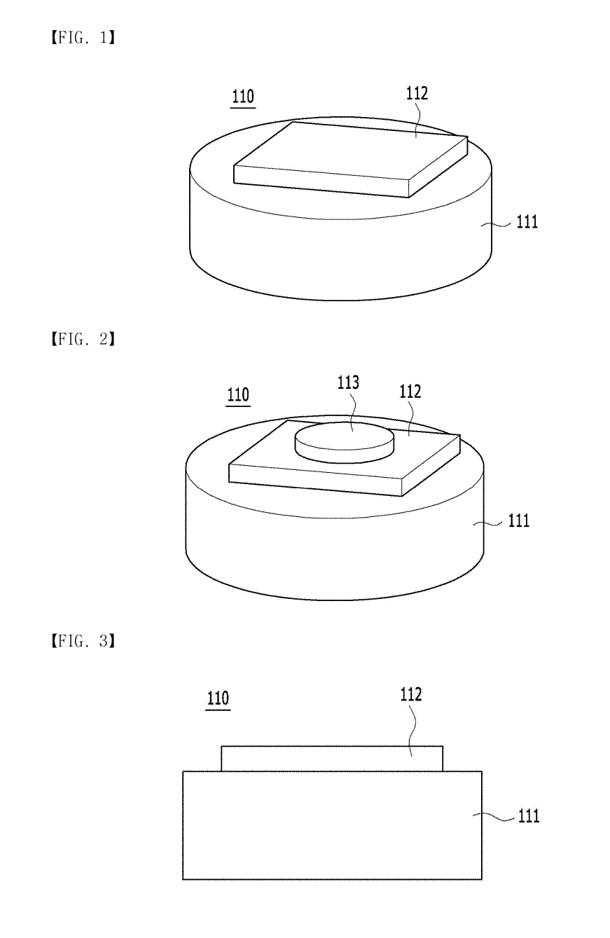

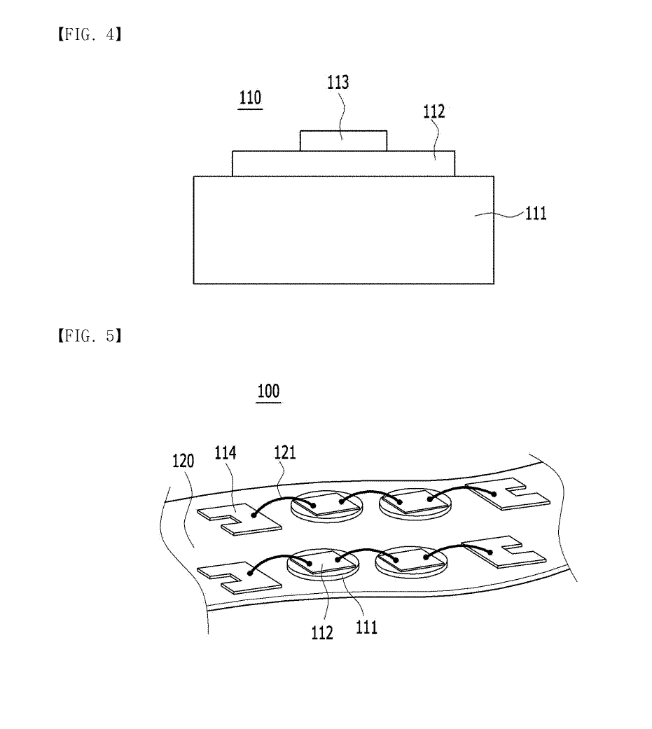

FIG. 1 is a perspective view of a spin thermoelectric element in a spin thermoelectric device according to an embodiment of the present invention; FIG. 2 is a perspective view of a hybrid spin thermoelectric element in a spin thermoelectric device according to an embodiment of the present invention; FIG. 3 is a cross-section view of a spin thermoelectric element in a spin thermoelectric device according to an embodiment of the present invention; FIG. 4 is a cross-section view of a hybrid spin thermoelectric element in a spin thermoelectric device according to an embodiment of the present invention; FIG. 5 is a perspective view of a spin thermoelectric device according to an embodiment of the present invention; and FIG. 6 is a perspective view of a spin thermoelectric device according to an embodiment of the present invention;

Referring to FIG. 1 to FIG. 6, a spin thermoelectric device 100 according to an embodiment of the present invention includes a transparent base material 120, a plurality of spin thermoelectric elements 110 provided on the base material 120, and a plurality of electrode pads 114. The spin thermoelectric element 110 includes a thermoelectric layer 111 formed by a sol-gel method and made of a material that shows the spin Seebeck effect caused by a temperature gradient based on a heat source, and an electrode layer 112 formed on the thermoelectric layer 111.

Further, the transparent base material 120 is flexible to correspond to an application having a curved surface.

The electrode layer 112 may have various shapes such as a ladder shape, a quadrangle, a circle, etc. The electrode layer 112 may be made of platinum (Pt), but not limited thereto.

The thermoelectric layer 111 not only converts thermal energy into electrical energy according to the temperature gradient based on sunlight or the like heat source, but also serves as a substrate for supporting the electrode layer 112.

The thermoelectric layer 111 may contain a material that shows the spin Seebeck effect based on the temperature gradient. Representatively, the thermoelectric layer 111 may contain yttrium iron garnet (YIG, Y₃Fe₅O₁₂).

The thermoelectric layer 111 may be manufactured by the sol-gel method. The sol-gel method is expected to have effects on improving uniformity of the thermoelectric layer, enabling low-temperature synthesis and synthesis of new composition with rare-earth additives, and increasing the surface area of the thermoelectric layer by synthesis of particle ceramics (nano powder).

The sol-gel method employed in manufacturing the thermoelectric layer 111 refers to that colloidal particles obtained by hydrolysis or dehydration synthesis and having a size of several tens and hundreds of mm make silica particles obtained by flame hydrolysis of sol suspended in liquid be suspended in liquid, and thus the colloidal particles can be condensed and congealed in sol so that sol can lose fluidity and turn to porous gel.

The sol generally includes particles of about 1˜1000 nm as a solution with a dissolved reactant salt, which is called a suspension in which a colloid (i.e. a particle gel) or a solid inorganic single-molecule (i.e. polymeric gel) is suspended. In the suspension, attraction or gravity is so ignorable that the particles are not settled down but suspended like a colloid by van der Waals force or surface charge. A precursor for forming the colloid includes metal surrounded with various reactive coordination compounds, and the sol turns to gel as its dispersion medium, i.e. a solvent.

On the contrary to the sol, the gel loses the fluidity as the reaction of the sol lasts and polymerizes the dispersed solid molecules, thereby forming a continuous solid network structure. Then, a hard ceramics is manufactured by thermally treating the gel which lost the fluidity.

Further, the electrode layer 112 is formed on the thermoelectric layer 111, and used in supplying power, which is generated as the thermal energy is converted into the electrical energy in the thermoelectric layer 111 according to the temperature gradient, to the outside of the spin thermoelectric element 110. The electrode layer 112 may be made of platinum (Pt) and formed on the thermoelectric layer 111 by a photolithography or direct-current (DC) sputtering processes.

If the electrode layer 112 is formed by the photolithography process using photoresist (PR) and a mask pattern, a positive resist or a negative resist may be used to form the electrode layer 112. In case of the positive photolithography process, the mask is patterned on an area where an electrode will be formed, and the PR solution is applied to the other area and then exposed to light, thereby forming the electrode in the area where the mask is patterned. In case of the negative photolithography process, the PR solution is applied to the area where the electrode will be formed, the mask pattern is formed on the other area, and the PR solution is exposed to light, thereby forming the electrode in the area where the PR solution is applied.

The positive and negative resists may be properly selected in the manufacturing process in accordance with the design of the electrode layer 112, to be advantageous to the design of the electrode pattern.

The spin thermoelectric element 110 may further include a concentrator photovoltaics (CPV) 113 formed on the electrode layer 112.

The electrode pad 114 may be used in outputting electricity, which is generated in the spin thermoelectric element 110, to an electronic component, a rechargeable battery or the like outside. The transparent base material 120 may include a polyester (PET) film or a polydimethylsiloxane (PDMS).

The polyester (PET) film has been widely used as materials for a package, a solar cell, an optical display and an easily available plastic bag, and is suitable for processing since it has printing suitability and uniformity in thickness and stiffness. Like this, the polyester (PET) film is excellent in mechanical properties, but has shortcomings of being less transformed due to low flexibility with respect to external tensile stress. Nevertheless, the polyester (PET) film used for the material of the solar cell may serve as a cover of a green house, and be thus applied for agricultural and industrial purposes in which the fluidity is not important and good blocking performance is required.

The polydimethylsiloxane (PDMS) film includes a polymer, which is relatively inexpensive among flexible materials, does not easily break under mechanical stress, and is able to be synthesized with other materials at room temperature.

Further, the polydimethylsiloxane (PDMS) film is excellent in adhesion with ceramic materials. According to the present invention, the spin thermoelectric element manufactured by the sol-gel method is attached to the transparent base material, and therefore there is an advantage of excellent adhesion between the spin thermoelectric element and the transparent base material made of the polydimethylsiloxane (PDMS) film.

The spin thermoelectric elements 110 may be connected to each other by an electrode line 121, and may be connected to the electrode pad 114 by the electrode line 121.

In these embodiments, the spin thermoelectric devices 100 and 200 are provided with the spin thermoelectric element 110 formed on the transparent base material 120 and generating electricity based on the temperature gradient. Thus, if the spin thermoelectric device 100 or 200 additionally includes a rechargeable battery or the like, it is applicable to cladding of a building, a greenhouse, etc. and is capable of transmitting light while being charged with electricity when there is sunlight or there is difference in temperature between the inside and the outside of the building, but discharging electricity when there is no sunlight or there is no difference in temperature between the inside and the outside of the building. Thus, the spin thermoelectric devices 100 and 200 are utilizable for lighting based on a light source, cooling/heating based on a heat source, etc.

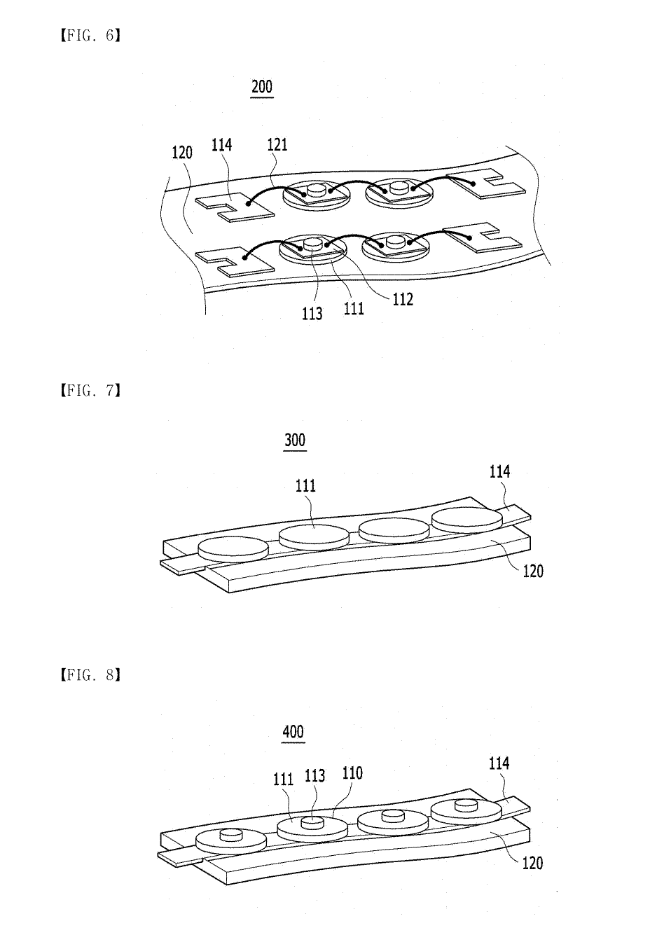

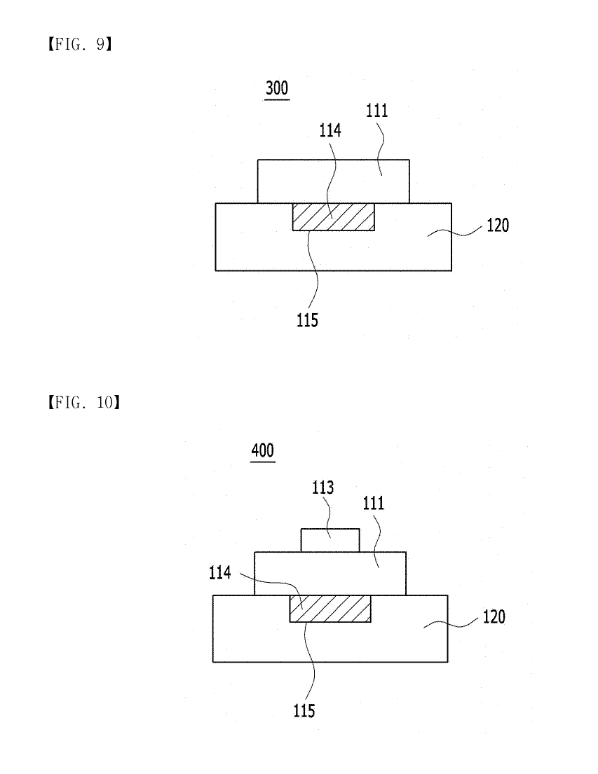

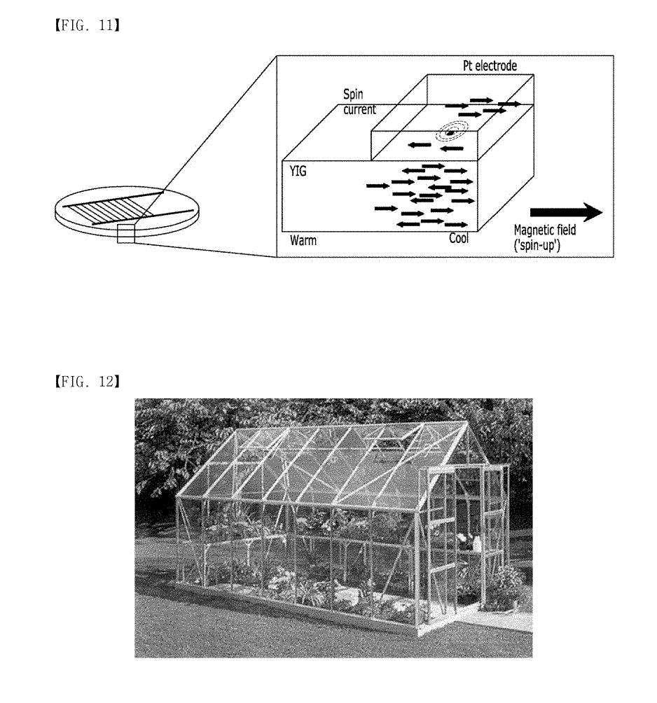

FIG. 7 is a perspective view of a spin thermoelectric device according to another embodiment of the present invention; FIG. 8 is a perspective view of a spin thermoelectric device according to another embodiment of the present invention; FIG. 9 is a cross-section view of a spin thermoelectric device according to another embodiment of the present invention; and FIG. 10 is a cross-section view of a spin thermoelectric device according to another embodiment of the present invention.

Referring to FIG. 7 to FIG. 10, the spin thermoelectric device 110 according to another embodiment of the present invention includes a transparent base material 120, a groove 115 formed on the base material, an electrode pad 114 formed to be filled in the groove 115, and a plurality of spin thermoelectric elements 110 provided on the base material 120 and the groove 115. The spin thermoelectric element 110 may be formed by the sol-gel method, and include the thermoelectric layer 111 made of a material that shows the spin Seebeck effect caused by the temperature gradient based on the heat source.

As shown in FIG. 8 and FIG. 10, the spin thermoelectric element 110 may further include the concentrator photovoltaics (CPV) 113 formed on the thermoelectric layer 111.

The electrode pad 114 may be used in supplying power, which is generated in the spin thermoelectric element 110, to the outside. The transparent base material 120 may be the polyester (PET) film or the polydimethylsiloxane (PDMS) film. The thermoelectric layer may be made of yttrium iron garnet (YIG, Y₃Fe₅O₁₂).

Spin thermoelectric devices 300 and 400 in these embodiments have simpler structures than those of the foregoing embodiments since a groove 115 is formed on the transparent base material 120 and the groove 115 is filled with the electrode pad 114 so that the spin thermoelectric elements 110 can be electrically connected without additional electrode lines.

FIG. 12 illustrates one of the application fields of the spin thermoelectric device according to the present invention.

Referring to FIG. 12, the spin thermoelectric device according to the present invention may be applicable to a greenhouse or the like building having the transparent outer wall.

If the thermoelectric device according to the present invention is applied to the greenhouse or the like, the spin thermoelectric device according to an embodiment of the present invention and the rechargeable battery to be charged with electricity generated in the spin thermoelectric device are provided to be charged when there is a heat source such as sunlight or to discharge electricity and emit light if there are no heat sources.

In other words, the spin thermoelectric device 100, 200, 300, 400 with the spin thermoelectric element 110 facing toward the outside of the building or the greenhouse is charged with electricity if there is a heat source such as sunlight, but discharges the electricity to emit light if there are no heat sources, thereby serving as the light or other energy sources in the greenhouse, the building or the like having the transparent outer wall.

As described above, the spin thermoelectric device according to the present invention includes the spin thermoelectric element, which has the thermoelectric layer formed by the sol-gel method and made of the material showing the spin Seebeck effect caused by the temperature gradient based on the heat source, and the electrode layer formed on the thermoelectric layer, and is placed on the transparent base material. If the spin thermoelectric device is additionally provided with and the rechargeable battery or the like, the spin thermoelectric device may be applied to cladding of building, a greenhouse, etc. and used as both the light source for lighting and the heat source for cooling/heating in such a manner that it transmits light and is charged with electricity when there is sunlight or there is difference in temperature between the inside of the building and the outside and it discharges electricity when there is no sunlight or there are no differences in temperature between the inside of the building and the outside.

The foregoing detailed descriptions illustrate the present invention, Further, the foregoing descriptions are nothing but the exemplary embodiments of the present invention, and the present invention may be utilized under various combinations, modifications and conditions. That is, the foregoing descriptions are changeable or modifiable within the scope of the invention disclosed in this specification, the scope equivalent to the disclosure and/or the scope of technology or knowledge related to this art. The foregoing embodiments are just given for explaining the best mode in realizing the present invention, and may be differently realized by another mode as known in the art or variously changed as required in detailed fields or usage of the present invention. Accordingly, the foregoing detailed descriptions are not intended to limit the present invention to the foregoing embodiments. Further, appended claims have to be construed as including other embodiments.

### REFERENCE NUMERALS

100, 200, 300, 400: spin thermoelectric device
110: spin thermoelectric element
111: thermoelectric layer
112: electrode layer
113: concentrator photovoltaics (CPV)
114: electrode pad
120: transparent base material
121: electrode line
130: light source (LED, light bulb)
500: greenhouse
510: outer wall
520: rechargeable battery

What is claimed is:

1. A spin thermoelectric device comprising:
a transparent base material; and
a plurality of spin thermoelectric elements and a plurality of electrode pads which are provided on the base material,
wherein the spin thermoelectric element comprises a thermoelectric layer formed by a sol-gel method and made of a material that shows a spin Seebeck effect caused by a temperature gradient based on a heat source, and an electrode layer formed on the thermoelectric layer.

2. The spin thermoelectric device according to claim 1, wherein the spin thermoelectric element further comprises a concentrator photovoltaics (CPV) formed on the electrode layer.

3. The spin thermoelectric device according to claim 1, wherein the base material is flexible.

4. The spin thermoelectric device according to claim 2, wherein the base material is flexible.

5. The spin thermoelectric device according to claim 1, wherein the electrode pad is used in outputting electricity generated in the spin thermoelectric element to an outside.

6. The spin thermoelectric device according to claim 2, wherein the electrode pad is used in outputting electricity generated in the spin thermoelectric element to an outside.

7. The spin thermoelectric device according to claim 1, wherein the transparent base material comprises a polyester (PET) film or a polydimethylsiloxane (PDMS) film.

8. The spin thermoelectric device according to claim 2, wherein the transparent base material comprises a polyester (PET) film or a polydimethylsiloxane (PDMS) film.

9. The spin thermoelectric device according to claim 1, wherein the thermoelectric layer comprises yttrium iron garnet (YIG, Y₃Fe₅O₁₂).

10. The spin thermoelectric device according to claim 2, wherein the thermoelectric layer comprises yttrium iron garnet (YIG, Y₃Fe₅O₁₂).

11. A spin thermoelectric device comprising:
a transparent base material;
a groove formed on the base material;
an electrode pad filled in the groove; and
a plurality of spin thermoelectric elements provided on the base material and the groove,
wherein the spin thermoelectric element comprises a thermoelectric layer formed by a sol-gel method and made of a material that shows a spin Seebeck effect caused by a temperature gradient based on a heat source.

12. The spin thermoelectric device according to claim 11, wherein the spin thermoelectric element further comprises a concentrator photovoltaics (CPV) formed on the thermoelectric layer.

13. The spin thermoelectric device according to claim 11, wherein the base material is flexible.

14. The spin thermoelectric device according to claim 12, wherein the base material is flexible.

15. The spin thermoelectric device according to claim 11, wherein the electrode pad is used in outputting electricity generated in the spin thermoelectric element to an outside.

16. The spin thermoelectric device according to claim 12, wherein the electrode pad is used in outputting electricity generated in the spin thermoelectric element to an outside.

17. The spin thermoelectric device according to claim 11, wherein the transparent base material comprises a polyester (PET) film or a polydimethylsiloxane (PDMS) film.

18. The spin thermoelectric device according to claim 12, wherein the transparent base material comprises a polyester (PET) film or a polydimethylsiloxane (PDMS) film.

19. The spin thermoelectric device according to claim 11, wherein the thermoelectric layer comprises yttrium iron garnet (YIG, Y₃Fe₅O₁₂).

20. The spin thermoelectric device according to claim 12, wherein the thermoelectric layer comprises yttrium iron garnet (YIG, Y₃Fe₅O₁₂).
